(19) United States
(12) Patent Application Publication
(10) Pub. No.: US 2015/0380309 A1
(43) Pub. Date: Dec. 31, 2015

(54) Metal-insulator-semiconductor (MIS) contact with controlled defect density

(71) Applicants: Intermolecular Inc., San Jose, CA (US); GLOBALFOUNDRIES, Inc., Grand Cayman (KY)

(72) Inventors: Salil Mujumdar, San Jose, CA (US); Amol Joshi, Sunnyvale, CA (US); Kevin Kashefi, San Ramon, CA (US); Albert Sanghyup Lee, Cupertino, CA (US); Abhijit Pethe, San Jose, CA (US); Bin Yang, San Carlos, CA (US)

(21) Appl. No.: 14/315,718

(22) Filed: Jun. 26, 2014

(51) Int. Cl. H01L 21/768; H01L 23/535

(52) U.S. Cl. CPC H01L 21/76895; H01L 23/535

(57) ABSTRACT

Metal-insulator-semiconductor (MIS) contacts for germanium and its alloys include insulator layers of oxygen-deficient metal oxide deposited by atomic layer deposition (ALD). The oxygen deficiency reduces the tunnel barrier resistance of the insulator layer while maintaining the layer's ability to prevent Fermi-level pinning at the metal/semiconductor interface. The oxygen deficiency is controlled by optimizing one or more ALD parameters such as shortened oxidant pulses, use of less-reactive oxidants such as water, heating the substrate during deposition, TMA “cleaning” of native oxide before deposition, and annealing after deposition. Secondary factors include reduced process-chamber pressure, cooled oxidant, and shortened pulses of the metal precursor.

### BACKGROUND

Related fields include semiconductor manufacture, particularly devices using germanium (Ge) as the semiconductor.

Transistors, such as metal-oxide-semiconductor field-effect transistors (MOSFETS) may be thought of as digital switches with low resistance in an “ON” state (Rₒₙ) and high resistance in an “OFF” state (Rₒₙ). It is desirable to increase the difference ΔR=R_{off}−Rₒₙ between the states. To a first approximation, a transistor's total resistance corresponds to the source contact resistance, the channel resistance, and the drain contact resistance connected in series. Channel resistance can be reduced by using a higher-mobility material for the channel; for instance, by using a Ge channel instead of silicon (Si). Unfortunately, with decreasing channel length, contribution of the source and drain contact resistances play a significant role in the overall device resistance. Metal contacts to n-Ge are observed to have large Schottky barriers, close to 0.6 eV, and consequently poor contacts. The Schottky barrier height in n-Ge is nearly independent of the metal's work function.

The cause is believed to be Fermi-level pinning from metal bonding directly to Ge at the interface. Interface dipoles, metal-induced gap states (MIGS), fixed charge, and other mechanisms have been proposed to explain the effect. In other materials, a high concentration of active dopants in the semiconductor can reduce the Schottky barrier height, but this has been difficult to achieve in Ge.

To alleviate Fermi level pinning, and thus lower the contact resistance, ultra-thin interface layers of insulating materials have been inserted between the metal and the Ge. This approach is known as a metal-insulator-semiconductor (MIS) contact. Interface materials for Ge include Ge₃N₄, SiOₓN_{y}, GeOₓ, AlOₓ, MgO, TiO₂, and others. If the insulating interface layer is sufficiently thin, electrons can tunnel through from the metal to the Ge and vice versa, but the metal and the Ge cannot bond to each other. However, the interface layer contributes a tunneling resistance of its own to the overall contact resistance. Traditionally, Schottky barrier reduction (helped by making the insulating layer thicker) and tunneling-resistance reduction (helped by making the insulating layer thinner) have therefore been traded off against each other in search of a minimum total contact resistance.

Materials with low band offsets to n-Ge, such as TiO₂ and SrTiO₃, provide low intrinsic tunneling resistance and a gradual increase in contact resistance with thickness. However, it is desirable to produce low contact resistance in a larger range of materials.

Therefore, a need exists for an insulating layer for an MIS contact to Ge that, while effectively blocking the metal-Ge bonds that cause Fermi-level pinning, contributes minimal tunneling resistance of its own and thus results in an overall lower contact resistance.

### SUMMARY

The following summary presents some concepts in a simplified form as an introduction to the detailed description that follows. It does not necessarily identify key or critical elements and is not intended to reflect a scope of invention.

Embodiments of oxide insulating layers for MIS contacts have intentionally elevated defect density to raise their conductivity. The defects are caused by the layer's containing a sub-stoichiometric amount of oxygen (the layer is “oxygen-deficient”). These layers provide enough physical separation between the surrounding metal and Ge layers to prevent Fermi pinning, but their heightened conductivity reduces tunneling resistance to decrease the total contact resistance. Increasing the defects can produce low contact resistance even in insulating materials with normally high band offsets from Ge, such as aluminum oxide (Al₂O₃) and hafnium oxide (HfO₂), as well as materials with low band offsets such as titanium oxide (TiO₂) and tantalum oxide (Ta₂O₅).

Embodiments of methods for making the oxygen-deficient oxide layers include atomic layer deposition (ALD). The methods may include heating the substrate to about 400 C during deposition and using very short (about 0.1 s) pulses of water (H₂O) as the oxidant. Optionally, the substrate may be pre-cleaned with trimethylaluminum (TMA) to remove any native germanium oxides (GeOx) before deposition. Optionally, the substrate may be annealed at about 400 C after deposition. Optionally, the pulse of metal precursor may also be shortened to 0.1 s, or the oxidant source may be maintained at a temperature of about 1 C, or the process pressure may be less than about 0.4 Torr. Any or all of the optional aspects may be combined.

### BRIEF DESCRIPTION OF DRAWINGS

The accompanying drawings may illustrate examples of concepts, embodiments, or results. They do not define or limit the scope of invention. They are not drawn to any absolute or relative scale. In some cases, identical or similar reference numbers may be used for identical or similar features in multiple drawings.

FIGS. 1A and 1B conceptually illustrate a transistor and the contributions of contact and channel resistances.

FIG. 2 is a graph of Fermi level pinning in contacts to Ge made of various metals.

FIG. 3 conceptually illustrates a transistor with metal-insulator-semiconductor (MIS) contacts.

FIG. 4 is a block diagram of an example ALD apparatus.

FIGS. 5A-5D conceptually illustrate construction of a MIS contact with an ALD oxygen-deficient insulating layer.

FIGS. 6A-6C conceptually illustrate TMA cleaning.

FIG. 7 is a flowchart of an example process for forming an MIS contact with an oxygen-deficient insulating layer.

FIGS. 8A and 8B are graphs of experimental data for ALD aluminum-oxide MIS insulator layers on Ge.

### DETAILED DESCRIPTION OF EXAMPLE EMBODIMENTS

A detailed description of one or more example embodiments is provided below. To avoid unnecessarily obscuring the description, some technical material known in the related fields is not described in detail. Semiconductor fabrication generally requires many other processes before and after those described; this description omits steps that are irrelevant to, or that may be performed independently of, the described processes.

By default, singular articles “a,” “an,” and “the” (or the absence of an article) may encompass plural variations. For example, “a layer” may mean “one or more layers,” except where the text or context clearly indicates “only one layer.” Where a range of values is provided, each intervening value is encompassed within the invention unless the text or context clearly dictates otherwise. “About” or “approximately” contemplates up to 10% variation. “Substantially” contemplates up to 5% variation.

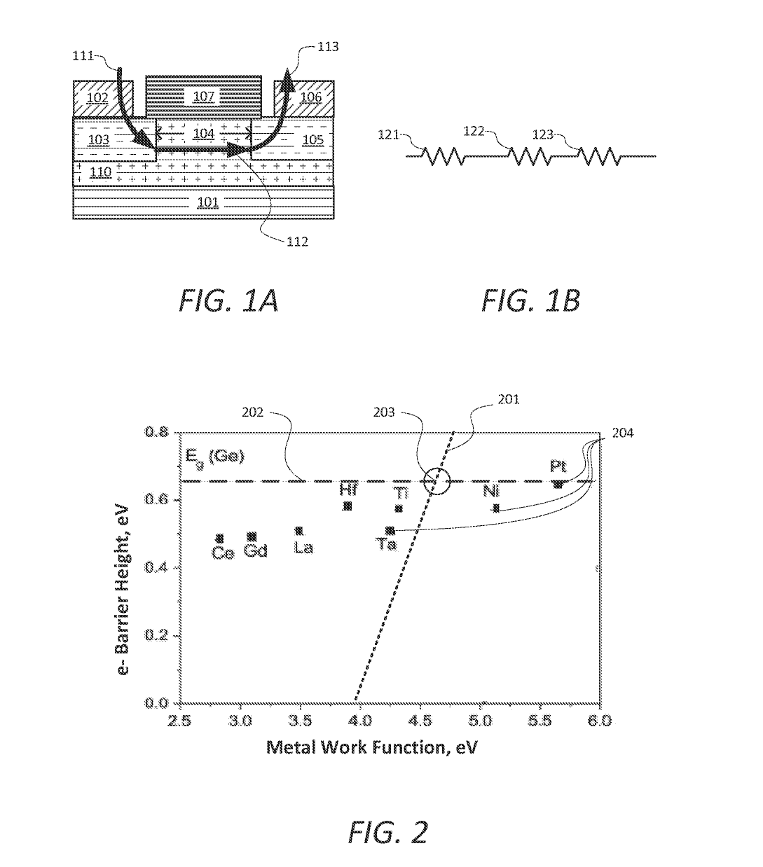

FIGS. 1A and 1B conceptually illustrate a transistor and the contributions of contact and channel resistances. In FIG. 1A, a semiconductor layer 110 (e.g., p-doped Ge) is formed on substrate 101. Source region 103 and drain region 105 (e.g., n-doped Ge) are formed around channel 104 in semiconductor layer 110. In some embodiments, source region 103 and drain region 105 are formed within semiconductor layer 110 by doping (e.g., though ion implantation or diffusion such as thermal diffusion). Gate (or gate stack) 107 is formed above channel 104. Source contact 102 is formed over source region 103, and drain contact 106 is formed over drain region 105. In practice, any of these components may have multiple substructures, and other components may be present.

FIG. 1B shows the equivalent schematic for the resistance of the transistor, to a first approximation: the sum of (1) the source contact resistance encountered on path 111, represented by resistor 121; (2) the channel resistance encountered on path 112, represented by resistor 122; and (3) the drain contact resistance encountered on path 113, represented by resistor 123. Channel resistance 122 is reduced by using Ge instead of Si for the channel material. However, the Fermi-level pinning at the interfaces between source contact 102 and source 103, and between drain contact 106 and drain 105, causes contact resistances 121 and 123 to be higher for Ge-based resistors than for their Si-based counterparts.

FIG. 2 is a graph of Fermi level pinning in contacts to Ge made of various metals. Line 201 represents an ideal junction with no Fermi level pinning. Its slope is 1. Line 202 represents the bandgap energy of Ge (˜0.67 eV at temperature=302K). At point 203, ideal-junction line 201 crosses Ge-bandgap energy 202; a metal with the work function equal to the x-coordinate of point 203 (˜4.7 eV) would be expected to form an ohmic contact with Ge. However, because of the Fermi pinning, this does not occur. The square data points (e.g., 204) show measured values of electron barrier height vs. metal work function for various contact metals: cerium (Ce), gadolinium (Gd), lanthanum (La), hafnium (Hf), tantalum (Ta), titanium (Ti), nickel (Ni), and platinum (Pt). A completely pinned junction would have a barrier height independent of the metal work function (slope of 0). The Ge junction is not quite completely pinned, but it is fairly close.

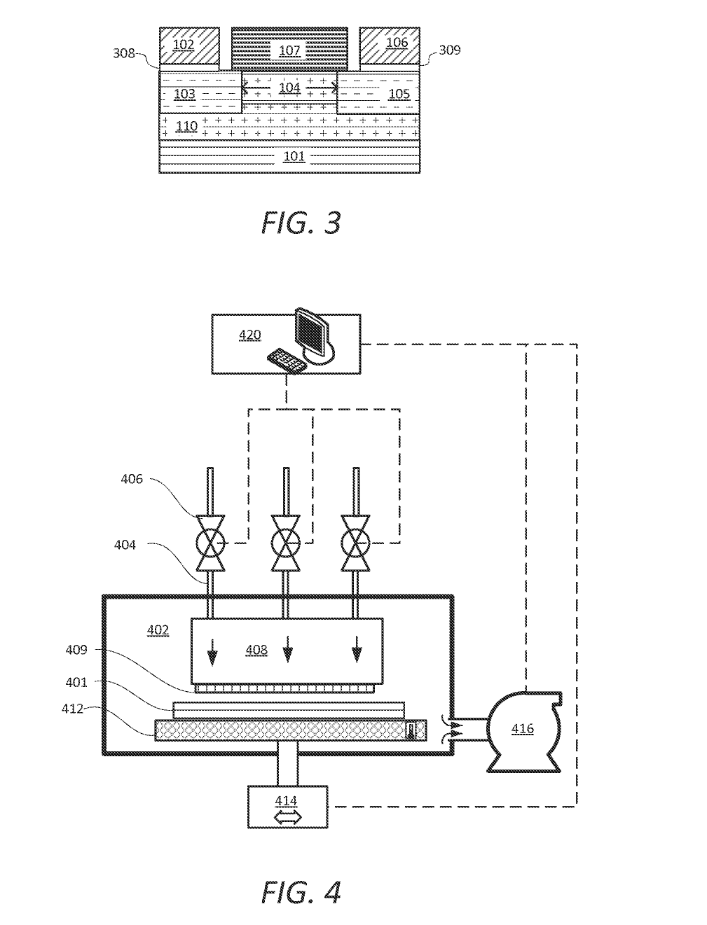

FIG. 3 conceptually illustrates a transistor with metal-insulator-semiconductor (MIS) contacts. An insulating layer 308 separates metal source contact 102 from semiconductor (e.g., n-Ge) source region 103. Similarly, an insulating layer 309 separates metal source contact 106 from semiconductor (e.g., n-Ge) source region 105. Insulating layers 308 and 309 prevent interface bonding between the metal and the Ge, and thus prevent Fermi-level pinning. However, electrons must now tunnel through insulating layers 308 and 309 if current is to traverse the transistor. The thicker and less-conductive the insulator is, the more tunnel resistance it will contribute to the contact resistance.

Although the examples herein specify Ge as the semiconductor, the solutions herein may also be applied to silicon-germanium (SiGe), other Ge-containing alloys, or other substrates such as III-V materials that suffer from similar Fermi-level pinning problems and make use of MIS contacts.

Certain types of defects in insulating layers create paths for current to leak through. Oxygen vacancies—places in an oxide where an oxygen atom could be bonded, but is not—are one such type of defect. In an oxide with oxygen vacancies, electrons need only tunnel from one oxygen vacancy to another, rather than across the entire layer. In effect, they increase the conductivity of the otherwise-insulating oxide. In a capacitor dielectric, these defects contribute to leakage current and are highly undesirable. However, in an insulator layer for MIS contacts, more conductivity is desirable. With atomic layer deposition, very precise control of both thickness and defect density is possible.

Atomic layer deposition (ALD) is a process used to deposit conformal layers with atomic scale thickness control during various semiconductor processing operations. ALD may be used to deposit barrier layers, adhesion layers, seed layers, dielectric layers, conductive layers, etc. ALD is a multi-step self-limiting process that includes the use of at least two reagents.

Generally, a first reagent (“precursor”) is introduced into a process chamber containing a substrate. Precursor molecules, or parts of them, adsorb onto the surface of the substrate. (As used herein, “adsorb” may include chemisorption, physisorption, electrostatic or magnetic attraction, or any other interaction resulting in part of the precursor adhering to the substrate surface). Excess precursor and by-products (e.g., precursor ligands detached from the deposited material) are purged and/or pumped away from the substrate. A second reagent (e.g., water vapor, ozone, or plasma) is then introduced into the chamber and reacts with the adsorbed layer to form a deposited layer. The deposition reaction is self-limiting in that the reaction terminates once the initially adsorbed layer has fully reacted with the second reagent. Again, excess precursor and by-products (e.g., precursor ligands detached from the deposited material) are purged and/or pumped away from the substrate.

This sequence constitutes one deposition or ALD “cycle.” Alternatively, the cycle may be referred to as an “A-B” cycle, with the introduction and purge of the first precursor being the “A cycle” and the introduction and purge of the second precursor being the “B cycle.” The process is repeated to form the next layer, with the number of cycles determining the total deposited film thickness.

The self-limiting nature of the ALD process enables the formation of film layers with precision on the atomic or molecular scale. Among those skilled in the art, ALD layer thickness is typically expressed as an average thickness. A contiguous monolayer is one molecule thick. However, a non-contiguous monolayer, where there are empty spaces left between the deposited atoms, can be less than 1 molecule thick on average.

FIG. 4 is a block diagram of an example ALD apparatus. For clarity, some components that may be included with some ALD chambers, such as a substrate-loading port, substrate lift pins, and electrical feedthroughs, are not shown. Environmentally-controlled process chamber 402 contains substrate holder 412 to hold substrate 401 for processing. Substrate holder 412 may be made from a thermally conducting metal (e.g., tungsten, molybdenum, aluminum, nickel) or other like materials (e.g., a conductive ceramic) and may be temperature-controlled. Drive 414 may move substrate holder 412 (e.g., translate or rotate in any direction) during loading, unloading, process set-up, or sometimes during processing.

Process chamber 402 is supplied with process gases by gas delivery lines 404 (although three are illustrated, any number of delivery lines may be used). A valve and/or mass flow controller 406 may be connected to one or more of delivery lines 404 to control the delivery rates of process gases into process chamber 402. In some embodiments, gases are routed from delivery lines 404 into process chamber 402 through delivery port 408. Delivery port 408 may be configured to premix the process gases (e.g., precursors and diluents), shape the distribution of the process gases over the surface of substrate 401, or both. Delivery port 408, sometimes called a “showerhead,” may include a diffusion plate 409 that distributes the process gases through multiple holes. Vacuum pump 416 exhausts reaction products and unreacted gases from, and maintains the desired ambient pressure in, process chamber 402.

Controller 420 may be connected to control various components of the apparatus to produce a desired set of process conditions. Controller 420 may include one or more memory devices and one or more processors with a central processing unit (CPU) or computer, analog and/or digital input/output connections, stepper motor controller boards, and the like. In some embodiments, controller 420 executes system control software including sets of instructions for controlling timing, gas flows, chamber pressure, chamber temperature, substrate temperature, radio frequency (RF) power levels (if RF components are used, e.g., for process gas dissociation), and other parameters. Other computer programs and instruction stored on memory devices associated with controller 420 may be employed in some embodiments.

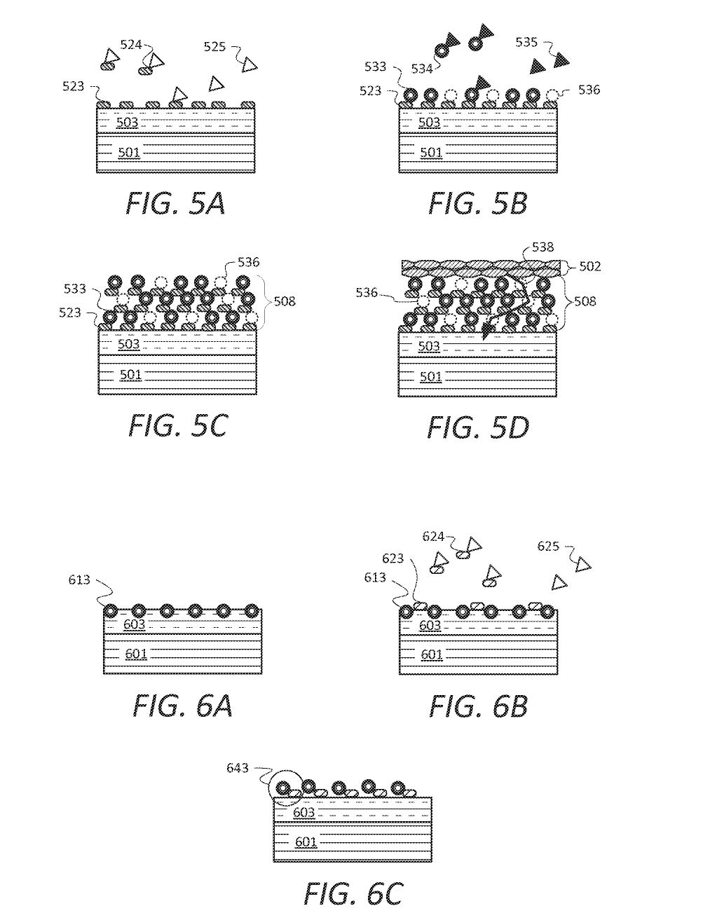

FIGS. 5A-5D conceptually illustrate construction of a MIS contact with an ALD oxygen-deficient insulating layer. As used herein, an “oxygen-deficient” metal oxide layer will be understood to contain less oxygen than at least one of the stoichiometric metal oxide compounds of that metal. For example, if a metal oxide has a stoichiometric formula MeO₂ (where Me represents the metal), then an oxygen-deficient compound would be MeO₍₂₋ₓ₎ with x>0. Although the same metal may have additional metal oxide compounds such as MeO, the MeO₍₂₋ₓ₎ layer would still be considered oxygen-deficient since it has less oxygen than the MeO₂ compound.

In FIG. 5A, substrate 501 with Ge layer 503 is exposed to metal precursor 524. For example, the metal precursor may be a precursor for aluminum (Al), titanium (Ti), hafnium (Hf) or tantalum (Ta). Typically, metal precursor 524 is made up of the metal component 523 (at least 1 metal atom) and at least one ligand 525. For instance, the Al precursor trimethylaluminum (TMA) includes 2 Al atoms and 6 methyl-group (CH₃) ligands. When a metal precursor molecule 524 encounters the surface of Ge layer 503, metal component 523 adsorbs to the surface and ligand 525 breaks away. The adsorption of metal stops when either (1) all the available bonding sites on the surface are filled, or (2) all the available metal precursor has been adsorbed, whichever comes first. The chamber is then purged with a purge gas (e.g., argon or nitrogen) to remove ligands 525, any unabsorbed precursors 524, and any other by-products.

In FIG. 5B, substrate 501 with Ge layer 503 and layer of adsorbed metal 523 is exposed to an oxygen precursor (or “oxidizer”) 534. The oxidizer may be oxygen gas (O₂) or ozone (O₃), but may alternatively be an oxygen component 533 (at least 1 oxygen atom) with at least one ligand 535. For instance, water vapor (H₂O) includes an O atom and 2 H atoms (which, once released, rapidly combine into H₂ under most circumstances). When an oxygen precursor molecule 534 encounters the surface of adsorbed metal 523, oxygen component 533 adsorbs to the surface and ligand 535 breaks away.

The adsorption of oxygen would normally stop when either (1) all the available bonding sites on the surface are filled, or (2) all the available oxygen precursor has been adsorbed, whichever comes first. However, to deposit an oxygen-deficient layer, the conditions are controlled so that fewer than all the available oxygen sites are filled and some unbonded oxygen sites 536 (“oxygen vacancies” or “dangling bonds”) are left at the end of the oxygen deposition cycle. Even if some Fermi-level pinning occurs with the unbonded metal atoms, the current will flow through the least-resistive path, so that the effective Schottky barrier height of the contact is almost equal to its lowest Schottky barrier height. The chamber is the purged with a purge gas (e.g., argon or nitrogen) to remove ligands 535, any unabsorbed precursors 534, and any other by-products, leaving an oxygen-deficient metal-oxide monolayer on the surface.

In FIG. 5C, the “A-B” (metal-oxygen) cycles have been repeated to create a metal-oxide layer 508 of multiple monolayers. At least some of the monolayers contain oxygen vacancies 536. In FIG. 5D, a metal layer 502 is formed over the metal-oxide layer 508. Other steps, such as annealing or surface treatments, may be executed between formation of metal-oxide layer 508 and metal layer 502. The metal layer may also be formed by ALD, or it may be formed by any other suitable method such as CVD or PVD. The metal layer may share a metal component with the metal-oxide layer, or not. Atoms from metal layer 502 cannot diffuse through metal-oxide layer 508, but electrons can tunnel through metal-oxide layer 508 along paths 538 between oxygen vacancies 536. Thus, this layer is an effective reaction barrier between the metal and Ge, and yet is conductive, so that the overall contact resistance is low.

FIGS. 6A-6C conceptually illustrate TMA cleaning. TMA “cleaning,” used to address unwanted native oxides that form on semiconductor surfaces, is actually an ALD deposition process. Instead of removing the oxygen entirely, the process deposits a material with a greater affinity for the oxygen than the semiconductor (in this case, aluminum) to scavenge the oxygen from the native oxide. In FIG. 6A, Ge layer 603 on substrate 601 has a layer of native oxide with bonded oxygen atoms 613. In FIG. 6B, the aluminum precursor TMA 624 is introduced in the chamber. The TMA 624 deposits aluminum 623 and releases methyl-group ligands 625. Without any oxidant being let into the chamber, the aluminum 623 scavenges the oxygen 613 from the native oxide layer, reducing Ge layer 603 to its un-oxidized state and forming a monolayer of aluminum oxide 643.

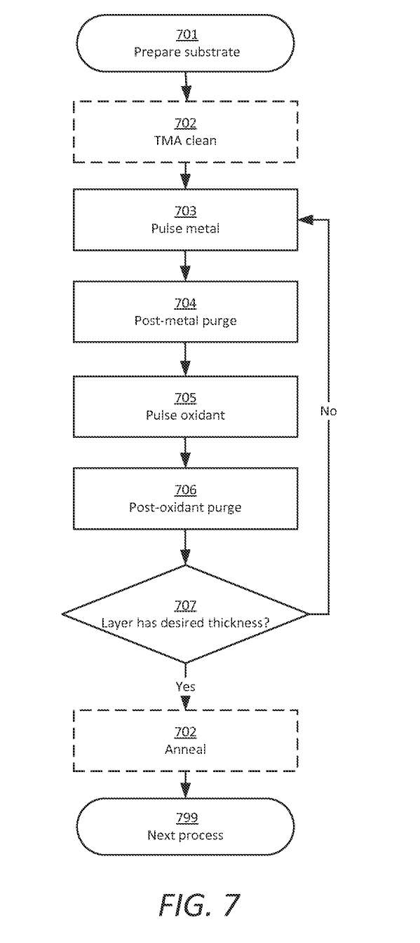

FIG. 7 is a flowchart of an example process for forming an MIS contact with an oxygen-deficient insulating layer. Initially, the substrate is prepared 701. Preparation of the substrate may include positioning it in the ALD chamber and heating it in a vacuum (e.g., 300-340 C at <0.1 Torr for 30-40 min) to drive off moisture and surface hydrocarbons. Optionally, the preparation may include removing native oxide from the semiconductor surface. Optionally, in some embodiments the substrate is TMA-cleaned 702. The TMA cleaning may include, for example, heating the substrate to 280-320 C and introducing 1-to-5-second pulses of TMA interspersed with 3-to-7-minute N2 purges at 5-10 Torr. The cycle may be repeated between 3 and 10 times.

Each ALD cycle for the oxygen deficient metal-oxide insulator includes metal pulse 703, post-metal purge 704, oxidant pulse 705, and post-oxidant purge 706 to create each monolayer (or sub-monolayer if some of the available bonding sites are left empty). The metal may include aluminum, titanium, hafnium, or tantalum. The metal precursor may include (for Al) aluminum tris(2,2,6,6-tetramethyl-3,5-heptanedionate) (Al(OCC(CH₃)₃CHCOC(CH₃)₃)₃), triisobutyl aluminum ([(CH₃)₂CHCH₂]₃Al), trimethyl aluminum ((CH₃)₃Al)—also known as TMA, Tris(dimethyl amido)aluminum (Al(N(CH₃)₂)₃); (for Ti) bis(tert-butylcyclopentadienyl)titanium(IV) dichloride, (C₁₈H₂₆Cl₂Ti), tetrakis(diethylamido)titanium(IV) ([(C₂H₅)₂N]₄Ti), tetrakis(diethylamido)titanium(IV) ([(C₂H₅)₂N]₄Ti), or tetrakis(dimethylamido)titanium(IV) ([(CH₃)₂N]₄Ti); (for Hf) bis(tert-butylcyclopentadienyl)dimethyl hafnium (C₂₀H₃₂Hf), bis(methyl-η5-cyclopentadienyl) methoxymethyl hafnium (HfCH₃(OCH₃)[C₅H₄(CH₃)]₂), bis(trimethylsilyl)amido hafnium chloride ([[(CH₃)₃Si]₂N]₂HfCl₂), dimethylbis(cyclopentadienyl)hafnium ((C₅H₅)₂Hf(CH₃)₂), hafnium isopropoxide isopropanol adduct (C₁₂H₂₈HfO₄), tetrakis(diethylamido) hafnium ([(CH₂CH₃)₂N]₄Hf)—also known as TEMAH, tetrakis(ethylmethylamido) hafnium ([(CH₃)(C₂H₅)N]₄Hf), tetrakis(dimethylamido) hafnium ([(CH₃)₂N]₄Hf)—also known as TDMAH, and hafnium tert-butoxide (HTB); (for Ta) pentakis(dimethylamino)tantalum(V) (Ta(N(CH₃)₂)₅), tantalum(V) ethoxide (Ta(OC₂H₅)₅), tris(diethylamido)(tert-butylimido)tantalum(V) ((CH₃)₃CNTa(N(C₂H₅)₂)₃), or tris(diethylamido)(tert-butylimido)tantalum(V) ((CH₃)₃CNTa(N(C₂H₅)₂)₃). The oxidant may include water (H₂O), peroxides (organic and inorganic, including hydrogen peroxide H₂O₂), oxygen (O₂), ozone (O₃), oxides of nitrogen (NO, N₂O, NO₂, N₂O₅), alcohols (e.g., ROH, where R is a methyl, ethyl, propyl, isopropyl, butyl, secondary butyl, or tertiary butyl group, or other suitable alkyl group), carboxylic acids (RCOOH, where R is any suitable alkyl group as above), and radical oxygen compounds (e.g., O, O₂, O₃, and OH radicals produced by heat, hot-wires, and/or plasma).

In some embodiments, the oxidant pulse is very short (e.g., 0.05-0.15 seconds) so that not enough oxygen is available to fully oxidize the metal and some oxygen vacancies are created in the monolayer. In some embodiments, the oxidant is H₂O. In some embodiments, the deposition temperature is between 190 C and 410 C, such as 200 C or 400 C. Optionally, the metal-precursor pulse may also be short (e.g., 0.05-0.15 seconds). Optionally, the oxidant source may be cooled to 0.5 C-3 C. Optionally, the chamber pressure may be maintained at less than 0.4 Torr.

Once the ALD cycles have produced the desired film thickness (0.5-4 nm or, preferably for some applications, 0.5-1.5 nm), fulfilling condition 707, the substrate may optionally be annealed 708 before beginning the next process 799. Annealing may be, for example, 25-35 min at 375-525 C, or 30 min at 400 C, or 30 min at 500 C, or a two-step anneal such as 30 min at 400 C followed by 30 min at 500 C.

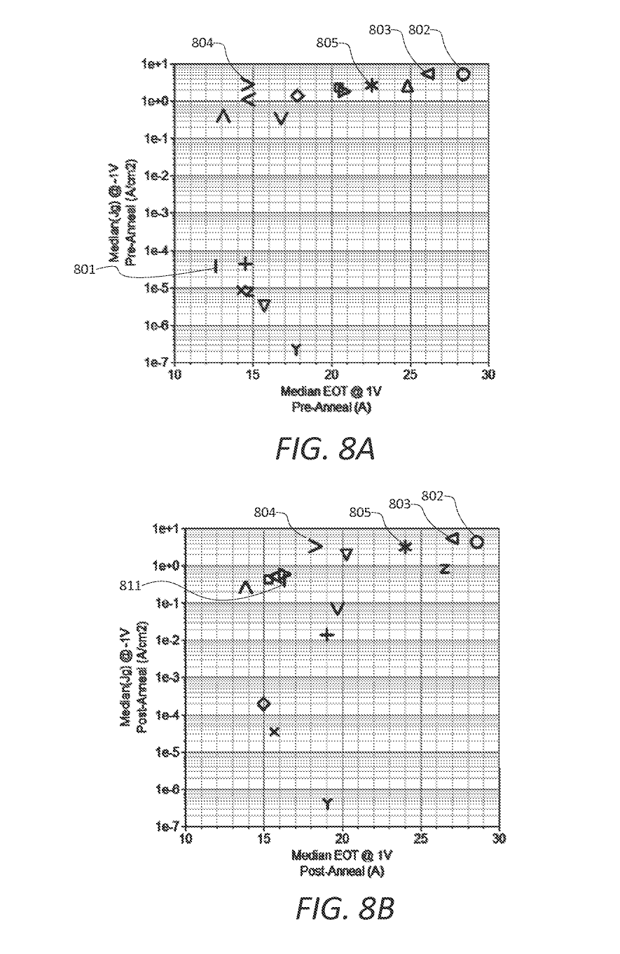

FIGS. 8A and 8B are graphs of experimental data for ALD aluminum-oxide MIS insulator layers on Ge. The test layers were 3 nm thick; considerably thicker than typical MIS insulator layers. FIG. 8A represents leakage current density J_{g} vs. effective oxide thickness EOT before annealing. EOT is in Ångstrom units (1 A=0.1 nm). EOT=t*(k_{SiO2}/kₘₐₜₗ), where t is the physical thickness of the layer, k_{SiO2} is the dielectric constant of silicon dioxide, and kₘₐₜₗ is the dielectric constant of the film material. Data point 801 was a reference film using O₃ as the oxidizer; all the other films used H₂O. The four highest-leakage films 802, 803, 804 and 805 all used a short (˜0.1 s) water pulse in the oxidation cycles. Three of those four (803, 804, 805) were deposited at 400 C while 802 was deposited at 200 C.

FIG. 8B represents leakage current density J_{g} vs. effective oxide thickness EOT after annealing for 30 min at 400 C in forming gas (a hydrogen-nitrogen mixture sometimes prepared by dissociating ammonia). Forming-gas annealing often increases contact resistance (i.e., decreases leakage current) in tunnel barriers by reducing fixed charge density. Here, for the test films that had the highest leakage before annealing, there was little to no change; the contact resistance was still very low. Data point 811 is the reference film that used O₃ as the oxidizer; all the other films used H₂O. Data point 812 is the film that produced data point 802 before anneal. Data point 813 similarly corresponds to 803, 814 to 804, and 815 to 805. The films made oxygen-deficient by oxidizing with a short water pulse, most of them deposited at 400 C, retained their high leakage after annealing. In another experiment (data not shown), an additional 30 min anneal at 500 C increased the leakage by an order of magnitude.

In conclusion, oxygen-deficient metal-oxide films produce a low-resistance MIS contact to Ge that survives processes such as forming-gas annealing. Even at relatively large thicknesses of ˜3 nm, the leakage current is greater than 0.1 A/cm² at −1V.

Although the foregoing examples have been described in some detail to aid understanding, the invention is not limited to the details in the description and drawings. The examples are illustrative, not restrictive. There are many alternative ways of implementing the invention. Various aspects or components of the described embodiments may be used singly or in any combination. The scope is limited only by the claims, which encompass numerous alternatives, modifications, and equivalents.

What is claimed is:

1. A method of forming a metal-insulator-semiconductor contact, the method comprising:
providing a substrate, wherein the substrate comprises a semiconductor surface;
forming a first layer above the semiconductor surface, wherein the first layer comprises an oxygen-deficient metal oxide, and wherein the forming uses an atomic layer deposition process; and
forming a second layer above the first layer, wherein the second layer comprises a metal.

2. The method of claim 1, wherein the semiconductor surface comprises germanium or a germanium alloy.

3. The method of claim 1, wherein the first layer comprises aluminum, hafnium, titanium, or tantalum.

4. The method of claim 1, wherein the forming of the first layer comprises using water as an oxidant.

5. The method of claim 1, wherein the forming of the first layer comprises maintaining the oxidant at a temperature between 0.5 C and 3 C.

6. The method of claim 1, wherein the forming of the first layer comprises using an oxidant pulse between 0.05 and 0.15 seconds in duration.

7. The method of claim 1, wherein the forming of the first layer comprises using a metal-precursor pulse between 0.05 and 0.15 seconds in duration.

8. The method of claim 1, wherein the first layer is formed at a temperature between 190 C and 410 C.

9. The method of claim 1, wherein the first layer is formed at a temperature of about 400 C.

10. The method of claim 1, wherein the first layer is formed at a pressure below 0.4 Torr.

11. The method of claim 1, wherein the preparing of the substrate comprises heating the substrate to between 300 C and 340 C in an ambient pressure less than 0.1 Torr.

12. The method of claim 1, wherein the preparing of the substrate comprises removing a native oxide from the semiconductor surface.

13. The method of claim 1, further comprising exposing the substrate to trimethylaluminum (TMA) after the preparing of the substrate and before the forming of the first layer.

14. The method of claim 13, wherein aluminum deposited on the semiconductor surface by the exposure to the TMA scavenges oxygen from a native oxide on the semiconductor surface.

15. The method of claim 1, further comprising annealing the substrate at a temperature of at least 400 C for at least 30 minutes after the forming of the first layer.

16. The method of claim 1, further comprising annealing the substrate at a temperature of at least 500 C for at least 30 minutes after the forming of the first layer.

17. A metal-insulator-semiconductor contact, comprising:
a semiconductor layer;
a second layer; and
an oxygen-deficient metal-oxide layer between the semiconductor layer and the second layer;
wherein the oxygen-deficient metal-oxide layer has a leakage current density greater than 0.1 A/cm² at −1 V.

18. The contact of claim 17, wherein the semiconductor surface comprises germanium or a germanium alloy.

19. The contact of claim 17, wherein the oxygen-deficient metal-oxide layer is between 0.5 nm and 4 nm thick.

20. The contact of claim 17, wherein the first layer comprises aluminum, hafnium, titanium, or tantalum.
